(19) United States
(12) Patent Application Publication
(10) Pub. No.: US 2026/0334124 A1
(43) Pub. Date: Oct. 22, 2026

(54) SUBSTRATE PROCESSING APPARATUS AND CLEANING METHOD

(71) Applicant: Tokyo Electron Limited, Tokyo (JP)

(72) Inventors: Naoki MATSUMOTO, Miyagi (JP); Masanori ASAHARA, Miyagi (JP); Masaya HERAI, Miyagi (JP)

(73) Assignee: Tokyo Electron Limited, Tokyo (JP)

(21) Appl. No.: 19/529,220

(22) Filed: Feb. 4, 2026

Related U.S. Application Data
(63) Continuation of application No. PCT/JP2024/027318, filed on Jul. 31, 2024.

(30) Foreign Application Priority Data
Aug. 10, 2023 (JP) 2023-131404

(51) Int. Cl. H10P 70/00; B23K 26/08; B23K 26/146; B23K 26/402; B23K 103/00; H10P 72/00

(52) U.S. Cl. CPC H10P 70/54; B23K 26/0823; B23K 26/146; B23K 26/402; H10P 72/0411; B23K 2103/56

(57) ABSTRACT

A substrate processing apparatus is a substrate processing apparatus for processing a substrate. The substrate processing apparatus includes: a processing chamber; a support located in the processing chamber; a liquid column supply located on an upper portion of the support and to supply a liquid column to a peripheral edge of the substrate; a laser beam irradiator to emit a laser beam propagating through the liquid column; and controller circuitry configured to control the supply of the liquid column toward a deposit at the peripheral edge of the substrate and control the laser beam to propagate through the liquid column to irradiate the deposit with the laser beam.

### CROSS-REFERENCE TO RELATED APPLICATIONS

This application is a bypass continuation application of international application No. PCT/JP2024/027318 having an international filing date of Jul. 31, 2024 and designating the United States, the international application being based upon and claiming the benefit of priority from Japanese Patent Application No. 2023-131404, filed on Aug. 10, 2023, the entire contents of each of which are incorporated herein by reference.

### TECHNICAL FIELD

The present disclosure relates to a substrate processing apparatus and a cleaning method.

### BACKGROUND

Patent Document 1 discloses a substrate processing apparatus including a rotator that rotates a substrate around a vertical rotation axis, a liquid supply that supplies a liquid to a peripheral edge of the substrate, a liquid holding member disposed close to at least a part of the peripheral edge of the substrate and forming a liquid-tight state with the peripheral edge, and a laser irradiator that causes a laser beam to enter the peripheral edge of the substrate through the liquid.

Further, Patent Document 2 discloses a substrate processing apparatus including a liquid holder that holds a liquid with an upper portion of a liquid level open, a substrate holder that holds a substrate in a tilted state from a horizontal plane and partially immerses a peripheral edge of the substrate in the liquid, and a laser irradiator that causes a laser beam to enter the peripheral edge of the substrate through the liquid.

### CITATION LIST

### Patent Documents

Patent Document 1: JP2016-107272A

Patent Document 2: JP2016-178211A

### SUMMARY

According to the technique of the present disclosure, deposits adhering to a vicinity of an outer end portion of a back surface of a substrate are appropriately removed.

One aspect of the present disclosure is a substrate processing apparatus for processing a substrate. The substrate processing apparatus includes: a processing chamber; a support located in the processing chamber; a liquid column supply located on an upper portion of the support and to supply a liquid column to a peripheral edge of the substrate; a laser beam irradiator to emit a laser beam propagating through the liquid column; and controller circuitry configured to control the supply of the liquid column toward a deposit at the peripheral edge of the substrate and control the laser beam to propagate through the liquid column to irradiate the deposit with the laser beam.

According to the present disclosure, a deposit adhering to a vicinity of an outer end portion of a back surface of a substrate can be appropriately removed.

### BRIEF DESCRIPTION OF DRAWINGS

The scope of the present disclosure is best understood from the following detailed description of exemplary embodiments when read in conjunction with the accompanying drawings.

FIG. 1 is a vertical sectional view schematically illustrating an example of a configuration of a wafer processing system.

FIG. 2 is an enlarged view of a main part in FIG. 1.

FIG. 3 is a flow chart illustrating main steps of BSP removing processing.

FIG. 4 is a diagram illustrating a state of a laser beam emitted from a condenser lens.

FIG. 5 is a vertical sectional view schematically illustrating another example of a configuration of a wafer processing apparatus.

FIG. 6 is a vertical sectional view schematically illustrating another example of the configuration of the wafer processing apparatus.

### DETAILED DESCRIPTION

In a manufacturing process of a semiconductor device, plasma etching processing is performed using a mask layer having a pattern thereon as a mask on an etching target layer formed by stacking on a surface of a semiconductor substrate (hereinafter referred to as a “wafer” as an example).

In the plasma etching processing, a deposit, which is a reaction product, is generated during etching and adheres to a vicinity of an outer end portion of a back surface of a wafer being processed (hereinafter, referred to as a backside polymer (BSP)). The BSP adhering to the wafer may be detached during processing or transfer of the wafer to contaminate the inside of the apparatus, which may cause a problem in the apparatus or affect a processing result of the wafer.

Therefore, for example, as disclosed in Patent Document 1 and Patent Document 2, processing for removing the BSP adhering to the vicinity of the outer peripheral portion of the wafer is performed. Specifically, in the method disclosed in Patent Document 1 and Patent Document 2, the peripheral edge of the wafer being processed, more specifically, the BSP adhering to the peripheral edge is covered with a liquid, and in this state, the BSP is removed by causing a laser beam to enter the peripheral edge of the wafer.

However, when the BSP is removed by the method disclosed in Patent Document 1 or Patent Document 2, it is necessary to focus the laser beam on the BSP, and adjustment of a focus depth may be necessary according to a deposition amount or a film thickness of the BSP, or the like, which makes the control complicated. When removing the BSP, the peripheral edge of the wafer needs to be covered with a liquid, and if the liquid penetrates into a device mounting area on a wafer surface, it may cause corrosion of the device. Therefore, the method of removing the BSP in related art has room for improvement.

The technique according to the present disclosure has been made in consideration of the above-described circumstances, and the polymer adhering to the vicinity of the outer end portion of the back surface of the substrate can be appropriately removed. Hereinafter, a wafer processing apparatus as a substrate processing apparatus according to the present embodiment and a wafer processing method as a cleaning method according to the present embodiment will be described with reference to the drawings. The same reference numerals will be given to elements having substantially the same functional configurations throughout the specification and the drawings, and redundant description thereof will be omitted.

### Wafer Processing System

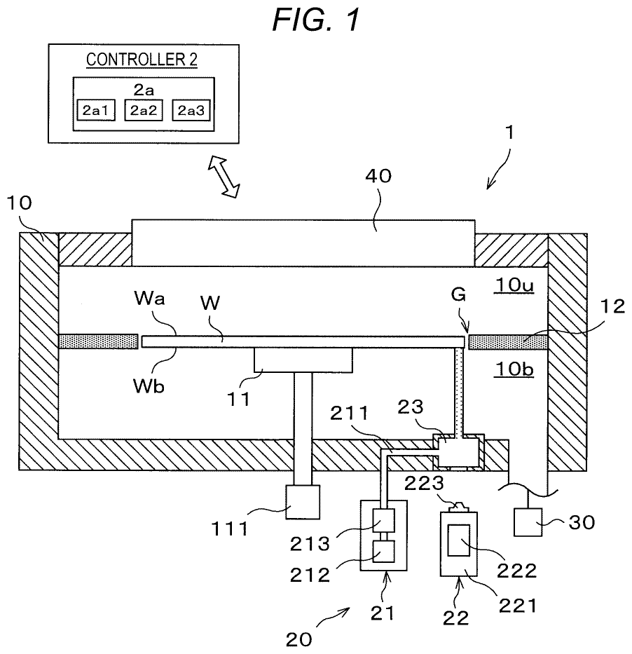

FIG. 1 is a vertical sectional view schematically illustrating an outline of a configuration of a wafer processing system.

In the wafer processing system, a BSP (deposit) adhering to a wafer W as a substrate is removed. The wafer W to be processed is, for example, a semiconductor wafer such as a semiconductor substrate, on which a device layer including devices is formed. Hereinafter, a surface of the wafer W on a side where the device layer is formed will be referred to as a front surface Wa, and a surface opposite to the front surface Wa will be referred to as a back surface Wb.

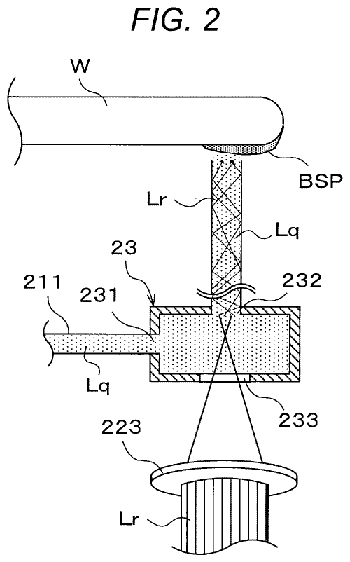

In one embodiment, the wafer processing system includes a wafer processing apparatus 1 and a controller 2 (herein “controller” means the same as “controller circuitry”). The wafer processing apparatus 1 removes the BSP (see FIG. 2) adhering to the wafer W under an atmospheric pressure environment. The wafer processing apparatus 1 includes a substantially cylindrical processing chamber 10 that accommodates the wafer W, a supply 20, and an exhausting portion 30. The processing chamber 10 includes a support member 11 and a shielding member 12 therein (herein “support member” means the same as a “support”).

The support member 11 holds the wafer W on an upper surface thereof. The support member 11 holds the back surface Wb of the wafer W with the front surface Wa of the wafer W facing up and the back surface Wb of the wafer W facing down. A structure of the support member 11 is not particularly limited, and for example, the support member 11 may be a vacuum chuck that vacuum-attracts the back surface Wb of the wafer W, or may be an electrostatic chuck that electrostatically attracts the back surface Wb of the wafer W. A rotating mechanism 111 is provided below the support member 11. The rotating mechanism 111 includes, for example, a motor therein as a drive source. The support member 11 is configured such that the wafer W held by the rotating mechanism 111 is rotatable around a vertical axis (herein “rotating driver” means the same as “rotating mechanism”).

The shielding member 12 is a substantially annular plate-shaped member disposed to surround a periphery of the wafer W held on the support member 11 (herein “shield” means the same as “shielding member.”). The shielding member 12 is fixed to a sidewall of the processing chamber 10 so as to form a slight gap G between the shielding member 12 and an outer peripheral end portion of the wafer W held on the support member 11. Accordingly, the shielding member 12 receives a liquid from the supply 20 to be described later, and prevents the liquid from adhering to a front surface side of the wafer W.

An interior space of the processing chamber 10 is divided into a lower space 10b and an upper space 10u by the wafer W held on the support member 11 and the shielding member 12. The lower space 10b functions as a processing space for removing the BSP adhering to the vicinity of the outer peripheral portion of the back surface Wb of the wafer W to be described later. The upper space 10u functions as a buffer space for preventing contamination of the front surface Wa side of the wafer W on which the device layer is formed when removing the BSP.

In the lower space 10b, the supply 20 and the exhausting portion 30 are provided to remove the BSP adhering to the back surface Wb of the wafer W held on the support member 11 through water laser processing (also referred to as water jet laser processing or water beam laser processing).

FIG. 2 is an enlarged view of a main part of the supply 20. As illustrated in FIGS. 1 and 2, the supply 20 includes a liquid supply mechanism 21, a laser irradiation mechanism 22, and a liquid chamber 23.

The liquid supply mechanism 21 serving as a liquid column supply includes a liquid supply path 211, at least one liquid supply source 212, and at least one flow rate controller 213. One end portion of the liquid supply path 211 is connected to the liquid chamber 23 to be described later, and the other end portion thereof is connected to the liquid supply source 212. The liquid supply mechanism 21 is configured to introduce at least one liquid from the corresponding liquid supply source 212 into the liquid chamber 23 through the corresponding flow rate controller 213. The liquid introduced into the liquid chamber 23 is supplied toward the back surface Wb of the wafer W held on the support member 11, more specifically, the BSP adhering to the wafer W to be described later. The flow rate controller 213 may include, for example, a mass flow controller or a pressure-controlled flow rate controller. The liquid supplied from the liquid supply mechanism 21 can be selected from, for example, pure water (DIW), ultrapure water (UPW), mixed acid of H₂O/NH₄OH/H₂O₂, mixed acid of H₂O/HCl/H₂O₂, functional cleaning water, and supercritical water. The liquid supplied from the liquid supply mechanism 21 to the back surface Wb of the wafer W is controlled by the flow rate controller 213 at a water pressure of 50 MPa at a maximum and a water amount of 0.05 L/min in one embodiment.

The laser irradiation mechanism 22 serving as a laser beam irradiator includes a laser head 221, an optical system 222, and a condenser lens 223. The laser head 221 includes a laser oscillator serving as a light source that oscillates a laser beam in a pulsed manner. The laser beam is a so-called pulsed laser. The type of the laser beam emitted from the laser head 221 is not particularly limited, and for example, a YAG laser or a femtosecond laser can be selected. The laser head 221 may include other components of the laser oscillator, such as an amplifier. In one embodiment, the optical system 222 includes an optical element that controls an intensity and a position of a laser beam, and an attenuator that attenuates a laser beam to adjust an output. The condenser lens 223 is a cylindrical member provided on an upper surface of the laser head 221, and irradiates, with the laser beam, the back surface Wb of the wafer W held on the support member 11, more specifically, the BSP adhering to the wafer W. In one embodiment, a diameter of the laser beam output from the laser head 221 is controlled to 20 μm, an output thereof is controlled to 100 W at maximum, and a frequency thereof is controlled to 60 KHz at maximum.

The liquid chamber 23 has a substantially cylindrical shape, and is disposed below the wafer W held on the support member 11 in the vicinity of the outer peripheral portion of the wafer W. As illustrated in FIG. 2, the liquid chamber 23 includes a liquid supply port 231, a liquid jetting hole 232, and an optical window 233.

In one embodiment, the liquid supply port 231 is formed on a side surface of the liquid chamber 23. The liquid supply port 231 is connected to one end portion of the liquid supply path 211 described above. Accordingly, the liquid from the liquid supply source 212 is introduced into the liquid chamber 23 through the liquid supply port 231.

In one embodiment, the liquid jetting hole 232 is formed in an upper surface of the liquid chamber 23 (surface on the back surface Wb side of the wafer W held on the support member 11). The liquid introduced into the liquid chamber 23 from the liquid supply source 212 is jetted as a laminar water jet liquid column and supplied toward the back surface Wb (BSP) of the wafer W through the liquid jetting hole 232, as described below. Accordingly, the liquid jetting hole 232 formed in the upper surface of the liquid chamber 23 has a function as a nozzle for supplying the liquid toward the back surface Wb of the wafer W. In one example, the liquid jetting hole 232 is formed to have a diameter of 50 μm to 100 μm. In other words, a diameter of the liquid column that is jetted from the liquid jetting hole 232 toward the back surface Wb of the wafer W is, for example, 50 μm to 100 μm.

In one embodiment, the optical window 233 is formed on a lower surface of the liquid chamber 23 (surface on the laser head 221 side). The optical window 233 transmits the laser beam from the condenser lens 223, and introduces the laser beam into the liquid chamber 23. The laser beam introduced into the liquid chamber 23 from the optical window 233 is emitted onto the back surface Wb (BSP) of the wafer W through the liquid jetting hole 232, as described later. At this time, the laser beam emitted from the liquid jetting hole 232 is totally reflected at a laminar water jet interface as illustrated in FIG. 2, and is confined in the liquid column under the principle of an optical fiber, and propagates until the laser beam reaches the back surface Wb (BSP) of the wafer W.

A distance from the back surface Wb of the wafer W to the liquid jetting hole 232 of the liquid chamber 23 is not particularly limited. In order to properly perform BSP removing processing in the wafer processing apparatus 1, it is preferable to determine the distance from the back surface Wb of the wafer W to the liquid jetting hole 232 of the liquid chamber 23 such that the liquid supplied from the liquid jetting hole 232 toward the back surface Wb of the wafer W does not diffuse and reaches the back surface Wb of the wafer W while maintaining the state of the laminar water jet liquid column.

In the present embodiment, as described above, the case where the liquid supply port 231, the liquid jetting hole 232, and the optical window 233 are respectively formed on the side surface, the upper surface, and the lower surface of the liquid chamber 23 has been described as an example. However, the disposition of the liquid supply port 231, the liquid jetting hole 232, and the optical window 233 is not particularly limited, and may be appropriately changed according to disposition of various elements in the wafer processing apparatus 1. For example, in a case where the optical window 233 through which the laser beam is introduced and the liquid jetting hole 232 through which the laser beam is emitted are not disposed on facing surfaces, a mirror for changing an irradiation path of the laser beam may be disposed in the liquid chamber 23.

The supply 20 that supplies the liquid and the laser beam toward the back surface Wb of the wafer W, particularly, the liquid chamber 23 may include a movable mechanism that moves relatively with respect to the wafer W held on the support member 11. In this case, the supply 20 (particularly, the liquid chamber 23) may be configured to be movable in a vertical direction (distance direction) with respect to the wafer W, or may be configured to be movable in a horizontal direction (radial direction of the wafer W).

The exhausting portion 30 includes, for example, an exhausting line connected to a bottom of the processing chamber 10. In one embodiment, the exhausting line branches below the processing chamber 10 into a first line for exhausting the liquid used for removing the BSP, and a second line for exhausting the BSP detached from the back surface Wb of the wafer W. The exhausting line may include a pressure adjusting valve and a vacuum pump. The pressure adjusting valve adjusts a pressure in the plasma processing space 10s. The vacuum pump may include a turbo molecular pump, a dry pump, or a combination thereof. The exhausting line may include a filter or a buffer mechanism for collecting the liquid or the BSP to be exhausted. The first line and the second line may be shared by one line.

A measurement mechanism for measuring a deposition amount or a film thickness of the BSP adhering to the back surface Wb of the wafer W (hereinafter, may be referred to as simply “film thickness or the like”) may be disposed in the lower space 10b of the processing chamber 10 (hereinafter “film” means the same as “layer”). The type of the measurement mechanism is not particularly limited. In one example, the measurement mechanism may be an imaging mechanism that calculates the film thickness or the like of the BSP based on captured image data, or a length measurement sensor that calculates the film thickness or the like of the BSP based on a distance from a reference position to the back surface Wb of the wafer W, or the like.

The disposition of the measurement mechanism is not limited to the lower space 10b of the processing chamber 10, and the measurement mechanism may be disposed at any location as long as the film thickness or the like of the BSP adhering to the back surface Wb of the wafer W can be measured. In one example, the measurement mechanism may be disposed in a plasma processing apparatus that performs plasma processing on the wafer W, or may be disposed in a transfer apparatus that transfers the wafer W. In other words, the film thickness or the like of the BSP adhering to the back surface Wb of the wafer W may be obtained in the wafer processing apparatus 1 according to the present embodiment, or may be obtained in advance before the wafer W is loaded into the wafer processing apparatus 1.

Reference will be made again to FIG. 1.

In the upper space 10u of the processing chamber 10, a fan filter unit (FFU) 40 that forms a downward airflow (hereinafter, referred to as a downflow) within the processing chamber 10 is provided (herein “fan filter” means the same as “fan filter unit”). The fan filter unit 40 blows a cleaning gas downward into the processing chamber 10. The cleaning gas supplied from the fan filter unit 40 to the upper space 10u is drawn into the lower space 10b through the gap G formed between the wafer W held on the support member 11 and the shielding member 12 as the lower space 10b is suctioned by the exhausting portion 30 described above. Accordingly, the fan filter unit 40 forms a gas flow flowing from the upper space 10u toward the lower space 10b.

The controller 2 processes computer-executable instructions for instructing the wafer processing apparatus 1 to execute various steps described in the present disclosure. The controller 2 may be configured to control each element of the wafer processing apparatus 1 to execute the various steps described herein below. In an embodiment, part or all of the controller 2 may be included in the wafer processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the wafer processing apparatus 1 via a communication line such as a local area network (LAN). Further, the storage medium may be temporary or non-temporary medium. The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

While various exemplary embodiments have been described above, various additions, omissions, substitutions and changes may be made without being limited to the exemplary embodiments described above. In addition, other embodiments may be formed by combining elements in different embodiments.

For example, in the embodiment described above, the support member 11 disposed in the processing chamber 10 is configured to be rotatable around the vertical axis by the rotating mechanism 111. However, at least, it is sufficient that the wafer W held on the support member 11 and the supply 20 (particularly, the liquid chamber 23 serving as a nozzle) disposed on the lower surface side of the wafer W are configured to be relatively rotatable with respect to each other. Therefore, instead of the support member 11 (wafer W) being configured to be rotatable in the processing chamber 10, the supply 20 (particularly, the liquid chamber 23 serving as a nozzle) may be configured to be relatively movable with respect to a circumferential direction of the wafer W.

Similarly, in the embodiment described above, it is described that the supply 20 (particularly, the liquid chamber 23) is configured to be relatively movable with respect to the wafer W held on the support member 11 in the vertical direction and the horizontal direction by a movable mechanism. However, instead of the supply 20 being configured to be movable, the support member 11 (wafer W) may be configured to be movable in the vertical direction and the horizontal direction inside the processing chamber 10.

### Processing Flow in Wafer Processing System

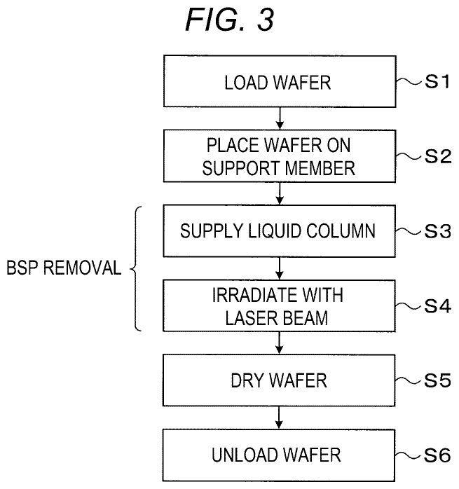

Next, wafer processing performed using the wafer processing system configured as described above will be described with reference to the drawings. FIG. 3 is a flow chart illustrating main steps of the BSP removing processing. In the present embodiment, the wafer W to be processed is previously subjected to etching processing in a plasma processing apparatus outside the wafer processing system.

First, the wafer W subjected to the etching processing in the plasma processing apparatus is loaded into the processing chamber 10 of the wafer processing apparatus 1 by a wafer transfer robot provided outside the wafer processing apparatus 1 (step S1 in FIG. 3). The wafer W loaded into the processing chamber 10 is held on the support member 11 at a substantially central portion of the back surface Wb thereof with the front surface Wa facing up and the back surface Wb facing down (step S2 in FIG. 3). In the vicinity of the outer peripheral portion of the back surface Wb of the wafer W being processed, a deposit generated during the plasma processing adheres as the BSP as illustrated in FIG. 2. The type of the BSP adhering to the wafer W is determined according to the type of the surface film of the wafer W subjected to the etching processing, and possible examples of the BSP include organic-based deposits such as fluorocarbons (CxFy), silicon-based deposits (Si, SiO, SiO₂) originating from the wafer W, metal-based deposits (Cu) originating from the device layer, metal-based deposits (W, Ti) originating from the mask material, and other metal-based deposits (Hf, Al, Ta).

Subsequently, after the inside of the processing chamber 10 is sealed, the BSP removing processing by the supply 20 is started. During the BSP removing processing, the formation of the downflow by the fan filter unit 40 and the suction of the processing chamber 10 by the exhausting portion 30 are simultaneously performed.

In the removing processing of the BSP adhering to the wafer W, first, the supply of a liquid Lq (for example, DIW or UPW) from the liquid supply mechanism 21 is started (step S3 in FIG. 3). The liquid Lq from the liquid supply mechanism 21 is introduced into the liquid chamber 23 from the liquid supply source 212 through the liquid supply path 211, and then jetted as a laminar water jet liquid column from the liquid jetting hole 232 toward the back surface Wb of the wafer W, more specifically, the BSP adhering to the wafer W. In one example, a BSP adhesion range (cleaning range in the present application) on the back surface Wb of the wafer W is about 5 mm from an outer peripheral end portion of the wafer W.

Next, the laser irradiation mechanism 22 irradiates the back surface Wb (BSP) of the wafer W with a pulsed laser beam Lr (step S4 in FIG. 3). At this time, the laser beam Lr output from the laser head 221 passes through the optical window 233, and is condensed in the liquid chamber 23 by the condenser lens 223. Then, the laser beam Lr is totally reflected at an interface between the liquid Lq (liquid column) and air (outside of the liquid) by a laminar water jet jetted from the liquid jetting hole 232 of the liquid chamber 23, and is propagated to the BSP adhering to the back surface Wb of the wafer W and is emitted thereon. The laser beam Lr may be a continuous wave.

On the back surface Wb of the wafer W to which the liquid Lq is supplied and the laser beam Lr is emitted, the BSP is removed by the action of the liquid Lq and the laser beam Lr. Specifically, the emitted laser beam Lr is converted into heat on the back surface Wb of the wafer W according to the energy distribution. In other words, a temperature of the BSP increases due to the irradiation of the laser beam Lr, which causes the BSP to be modified and detached from the back surface Wb of the wafer W. The temperature increases due to the irradiation of the laser beam Lr, and the BSP detached from the back surface Wb of the wafer W is cooled and simultaneously removed by the supplied liquid Lq during a next irradiation interval of the pulsed laser beam Lr. Accordingly, the temperature of the BSP decreases due to the supply of the liquid Lq, thereby preventing the warpage of the wafer W caused by the temperature increase. The BSP removed from the back surface Wb of the wafer W is then exhausted to the outside of the processing chamber 10 through the exhausting portion 30.

When the BSP adhering to the back surface Wb of the wafer W is removed, the wafer W held on the support member 11 is rotated around the vertical axis by the rotating mechanism 111, and the liquid chamber 23 of the supply 20 is moved in the horizontal direction by a movable mechanism. Accordingly, the supply of the liquid Lq and the irradiation of the laser beam Lr are performed on an entire surface of the cleaning range of the back surface Wb of the wafer W in the wafer processing apparatus 1, that is, an entire outer peripheral portion and an entire width in a width direction, and the BSP can be appropriately removed on the entire surface of the cleaning range of the back surface Wb of the wafer W. Therefore, in the present embodiment, a position of the supply 20 (the liquid supply mechanism 21, the laser irradiation mechanism 22, or at least the liquid chamber 23), that is, a supply position of the liquid column and an irradiation position of the laser beam, is controlled according to a deposition amount and a film thickness of the BSP on the back surface of the wafer W.

When the removal of the BSP from the entire periphery of the back surface Wb of the wafer W is completed, the BSP removing processing in the wafer processing apparatus 1 is completed. That is, the irradiation of the laser beam Lr from the laser irradiation mechanism 22 is stopped, and the supply of the liquid Lq from the liquid supply mechanism 21 is stopped. At this time, the formation of the downflow by the fan filter unit 40 and the suction of the processing chamber 10 by the exhausting portion 30 are stopped. Before the stopping of the formation of the downflow by the fan filter unit 40 and the suction of the processing chamber 10 by the exhausting portion 30, the wafer W held on the support member 11 may be dried (the liquid Lq supplied to the back surface Wb side may be removed: step S5 in FIG. 3) by, for example, rotating the wafer W at a high speed by the rotating mechanism 111.

After the BSP removing processing in the wafer processing apparatus 1 is completed, the wafer W is delivered from the support member 11 to a wafer transfer robot disposed outside the wafer processing apparatus 1. When the wafer W is unloaded to the outside of the processing chamber 10 by the wafer transfer robot (step S6 in FIG. 3), a series of wafer processing in the wafer processing system is completed. <Operations and Effects of Technique of Present Disclosure >

As described above, according to the wafer processing method according to the technique of the present disclosure, the BSP adhering to the back surface Wb of the wafer W due to the plasma processing is removed using the water laser processing technique.

As described above, in the dry laser processing described in Patent Literature 1 or Patent Literature 2, the energy (processing force) of the laser beam is concentrated at the focal point, and diffuses thereafter, so that it is necessary to set the focal point of the emitted laser beam to be aligned with the BSP. More specifically, it is necessary to successively control the focus depth of the laser beam according to the film type, film thickness, or the like of the BSP, which causes a problem of complicated control. Since the BSP having a vapor pressure lower than that of an organic substance-based deposit, for example, a metal-based deposit is unlikely to be volatilized by a temperature increase caused by irradiation of the laser beam, the removal may be insufficient.

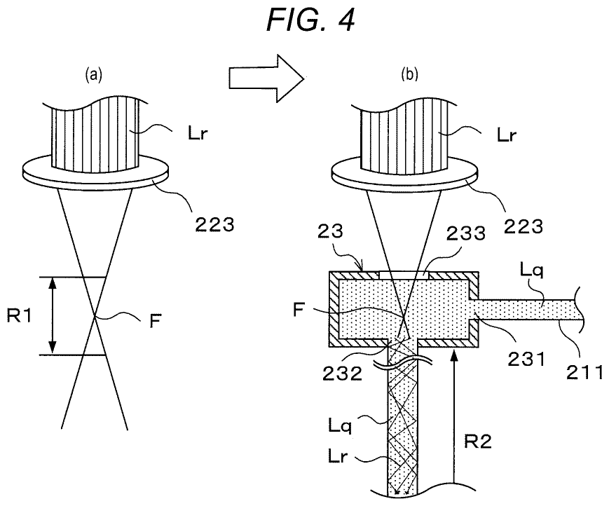

In this regard, in the water laser processing according to the present embodiment, total reflection of the laser beam Lr is utilized due to a difference in refractive index between water (inside the liquid column) and air (outside the liquid column). Therefore, the laser beam Lr is propagated through the liquid column like an optical fiber, which makes it unnecessary to control the focus depth of the laser beam Lr. In other words, a working range where the BSP can be removed by the laser beam Lr (distance range from the condenser lens 223) can be wider than that in the related art. Specifically, in the method in the related art, a working range R1 (see (a) of FIG. 4) using the laser beam Lr is limited to a predetermined distance range from a focal point F. However, in the method of the present application, a working range R2 (see, (b) of FIG. 4) using the laser beam Lr can be extended to a range beyond the focal point F where the liquid Lq can be supplied as a liquid column. Accordingly, the controllability with respect to the removal of the BSP and the flexibility of the disposition of the liquid chamber 23 serving as a nozzle are significantly improved.

At this time, instead of controlling the focus depth of the laser beam Lr, various types of BSP can be removed from the wafer W simply by controlling a laser intensity (amount of incident energy from the laser beam Lr to the BSP) according to, for example, the film thickness or the like of the BSP adhering to the wafer W or the film type.

Specifically, for example, when the film thickness of the BSP is large, in the method in the related art, it is necessary to set the focus depth to be deeper than that when the film thickness of the BSP is small, and in addition, it is necessary to control the laser intensity. However, in the method according to the present embodiment, the BSP can be removed with a resolution higher than that in the method in the related art simply by adjusting the laser intensity of the laser beam Lr.

According to the present embodiment, since the laser beam Lr can be totally reflected by the liquid column and the energy of the laser beam Lr can be efficiently transmitted to the BSP, by adjusting the laser intensity, the BSP can be properly removed from the wafer W even when the BSP is a BSP having a low vapor pressure that is not sufficiently removed by the dry laser processing in the related art.

For example, in the case of the BSP having a low vapor pressure, a part of the BSP that is easily peeled off can be removed by increasing a supply pressure of the liquid Lq, using a water force thereof (impact force caused by the collision of the liquid Lq). That is, by removing the part of the BSP that is easily peeled off using the water force of the liquid Lq, while simultaneously removing a remaining part thereof using the irradiated laser beam Lr, the BSP can be removed with a higher degree of cleanliness. In another aspect, according to the present embodiment, the part of the BSP that is not removed by the laser beam Lr and remains is removed by the water force of the liquid Lq, and thus the BSP can be removed with a higher degree of cleanliness.

A method of controlling the laser intensity of the laser beam Lr is not particularly limited. For example, the laser intensity may be controlled by controlling (pulse controlling) an amplitude, a cycle, and/or a duty ratio of a pulse emitted from the laser head 221. Alternatively, for example, an output power of the laser beam Lr from the laser head 221 may be increased.

According to the wafer processing method of the present embodiment, the laser beam Lr reaches the back surface Wb of the wafer W through the inside of the liquid Lq. Therefore, the BSP removing processing can be performed within a supply range of the liquid Lq on the back surface Wb of the wafer W, more specifically, within a range of 50 μm to 100 μm in diameter of the liquid column through which the liquid Lq is supplied. At the same time, since the BSP detached from the wafer W is removed by the water flow of the liquid Lq, scattering of the BSP into the inside of the wafer processing apparatus 1 after the BSP is detached from the wafer W can be prevented. Therefore, a removal area for removing the BSP can be set more pinpoint (smaller area) than in the method in the related art, and a freedom degree in control of the BSP removal is improved.

Since the BSP removal area can be set in a pinpoint manner as described above, the erosion of the liquid Lq on a mounting area of the device layer formed on the front surface Wa of the wafer W can be prevented more easily. Since the erosion of the liquid Lq on the mounting area of the device layer can be prevented as described above, the mounting area of the device layer formed on the front surface Wa of the wafer W can be further expanded to an outer peripheral end portion side.

According to the present embodiment, the inside of the wafer processing apparatus 1 is divided into the lower space 10b and the upper space 10u by the wafer W held on the support member 11 and the shielding member 12 disposed to surround the periphery of the wafer W. Accordingly, the liquid Lq supplied toward the back surface Wb of the wafer W or the BSP detached from the wafer W in the lower space 10b is received by the shielding member 12, and is prevented from scattering to the upper space 10u, that is, the front surface Wa side of the wafer W. Therefore, the contamination of the device layer formed on the front surface Wa of the wafer W by the liquid Lq or the removed BSP can be prevented.

Further, according to the present embodiment, inside the processing chamber 10, the downflow is formed by the fan filter unit 40 and the exhausting portion 30, flowing from the upper space 10u to the lower space 10b through the gap G formed between the outer peripheral end portion of the wafer W and the shielding member 12. Therefore, the liquid Lq supplied toward the back surface Wb of the wafer W or the BSP detached from the wafer W can be prevented from scattering to the upper space 10u, and the contamination of the device layer formed on the front surface Wa of the wafer W can be more appropriately prevented.

According to the present embodiment, when removing the BSP adhering to the back surface Wb of the wafer W, the irradiation of the laser beam Lr and the supply of the liquid Lq are performed at the same time. Therefore, the outer peripheral portion of the wafer W can be prevented from being locally heated by irradiation with the laser beam Lr, and as a result, warping of the wafer W due to temperature changes can be prevented.

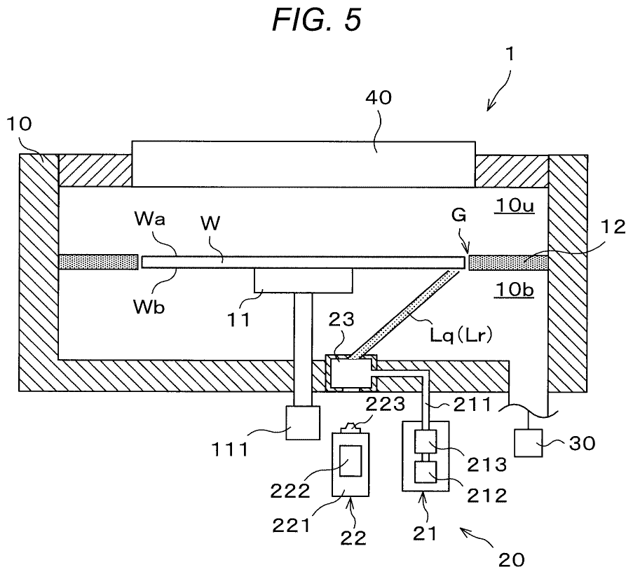

In the embodiment described above, the case where the supply 20 is disposed immediately below the outer peripheral end portion of the wafer W held on the support member 11, and the supply of the liquid Lq and the irradiation of the laser beam Lr are performed from immediately below the outer peripheral end portion of the wafer W has been described as an example, but the disposition of the supply 20 is not limited thereto. For example, as illustrated in FIG. 5, the supply 20 may be disposed immediately below the central portion of the wafer W held on the support member 11, or may be disposed obliquely below the outside of the wafer W in the radial direction, and the supply of the liquid Lq and the irradiation of the laser beam Lr may be performed obliquely upward toward the outer peripheral end portion of the wafer W. In this case, for example, by disposing the supply 20 immediately below the central portion of the wafer W and supplying the liquid Lq from the central side of the processing chamber 10 toward the outer peripheral end portion of the wafer W as illustrated in FIG. 5, scattering of the liquid Lq or the BSP to the upper space 10u of the processing chamber 10 may be more appropriately prevented.

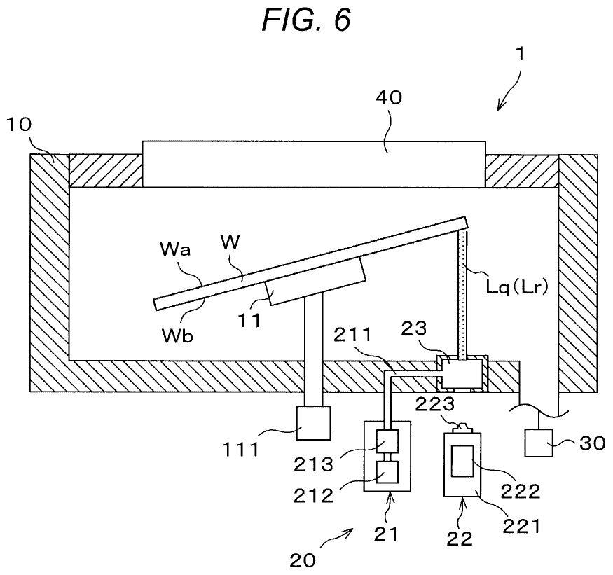

Instead of changing the disposition of the supply 20 as illustrated in FIG. 5, for example, the wafer W held on the support member 11 may be configured to be tiltable from the horizontal direction by a tilting mechanism as illustrated in FIG. 6, so that the supply of the liquid Lq and the irradiation of the laser beam Lr can be performed from a relatively oblique direction toward the outer peripheral end portion of the back surface Wb of the wafer W (herein “tilting structure” means the same as “tilting mechanism”).

The wafer processing apparatus 1 illustrated in the above embodiment has been described as an example of being configured independently as a cleaning apparatus that removes the BSP adhering to the back surface Wb of the wafer W. However, the wafer processing apparatus 1 that performs the BSP removing processing according to the technique of the present disclosure does not necessarily have to be configured as an independent apparatus, and the above-described BSP removing processing may be performed in any apparatus that performs the wafer processing under an atmospheric pressure atmosphere. Specifically, the configuration of the wafer processing apparatus 1 according to the technique of the present disclosure may be applied, for example, to a load lock module for transferring the wafer W between an atmospheric portion in an air atmosphere and a vacuum portion in a reduced-pressure atmosphere. In this case, a plasma processing apparatus that performs the etching processing on the wafer W can be disposed in a vacuum portion connected to the load lock module.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. A substrate processing apparatus for processing a substrate, the substrate processing apparatus comprising:
a processing chamber;
a support located in the processing chamber;
a liquid column supply located on an upper portion of the support and to supply a liquid column to a peripheral edge of the substrate;
a laser beam irradiator to emit a laser beam propagating through the liquid column; and
controller circuitry configured to control the supply of the liquid column toward a deposit at the peripheral edge of the substrate and control the laser beam to propagate through the liquid column to irradiate the deposit with the laser beam.

2. The substrate processing apparatus according to claim 1, wherein
the controller circuitry controls positions of the liquid column supply and the laser beam irradiator according to a deposition amount of the deposit at the peripheral edge of the substrate.

3. The substrate processing apparatus according to claim 1, wherein
the liquid column supply supplies the liquid column from below the substrate.

4. The substrate processing apparatus according to claim 3, further comprising:
a rotating driver to rotate the substrate on the support.

5. The substrate processing apparatus according to claim 3, further comprising:
a tilting structure to tilt the substrate on the support from a horizontal direction.

6. The substrate processing apparatus according to claim 3, further comprising:
a shield located to surround a periphery of the substrate on the support.

7. The substrate processing apparatus according to claim 3, further comprising:
a fan filter to supply clean air from above to below the processing chamber to form a downflow.

8. A cleaning method for removing a deposit adhering to a peripheral edge of a substrate, the cleaning method comprising:
loading the substrate having the deposit adhering to the peripheral edge into a processing chamber;
placing the substrate on a support; and
removing the deposit, wherein
the removing the deposit includes
supplying a liquid column toward the deposit adhering to the peripheral edge of the substrate, and
irradiating the liquid column with a laser beam.

9. The cleaning method according to claim 8, further comprising
controlling a supply position of the liquid column and an irradiation position of the laser beam according to a deposition amount of the deposit at the peripheral edge of the substrate.

10. The cleaning method according to claim 8, wherein
in the removing the deposit, supplying the liquid column from below the substrate.

11. The cleaning method according to claim 10, wherein
in the removing the deposit, rotating the substrate on the support.

12. The cleaning method according to claim 10, wherein
in the removing the deposit, tilting the substrate on the support from a horizontal direction.

13. The cleaning method according to claim 10, wherein
in the removing the deposit, forming a downflow in the processing chamber.

14. The substrate processing apparatus according to claim 2, wherein
the liquid column supply supplies the liquid column from below the substrate.

15. The substrate processing apparatus according to claim 1, wherein
the controller circuitry controls positions of the liquid column supply and the laser beam irradiator.

16. The substrate processing apparatus according to claim 4, further comprising:
a shield located to surround a periphery of the substrate on the support.

17. The cleaning method according to claim 9, wherein
in the removing the deposit, supplying the liquid column from below the substrate.

18. The cleaning method according to claim 8, further comprising
controlling a supply position of the liquid column and an irradiation position of the laser beam.

19. The cleaning method according to claim 11, wherein
in the removing the deposit, forming a downflow in the processing chamber.

20. A non-transitory computer-readable medium storing executable instructions, which when executed by controller circuitry, cause the controller circuitry to perform a method, the method comprising:
loading a substrate having a deposit adhering to a peripheral edge of the substrate into a processing chamber;
placing the substrate on a support; and
removing the deposit, wherein
the removing the deposit includes
supplying a liquid column toward the deposit adhering to the peripheral edge of the substrate, and
irradiating the liquid column with a laser beam.
